(19) United States
(12) Patent Application Publication
(10) Pub. No.: US 2026/0206190 A1
(43) Pub. Date: Jul. 16, 2026

(54) ENERGY-RADIATING COOLING AND TEMPERATURE-LOWERING SYSTEM

(71) Applicant: Meng-Theng WANG, New Taipei City (TW)

(72) Inventor: Meng-Theng WANG, New Taipei City (TW)

(21) Appl. No.: 19/023,383

(22) Filed: Jan. 16, 2025

(51) Int. Cl. H05K 7/20

(52) U.S. Cl. CPC H05K 7/20781

(57) ABSTRACT

An energy-radiating cooling and temperature-lowering system includes a refrigeration zone and a heat source zone arranged in an interior of a server mechanism and separated from each other by a metal separation plate. The metal separation plate serves as a heat exchange element between the refrigeration zone and the heat source zone. A refrigeration device is arranged in the refrigeration zone. The refrigeration device has a coolant pipe in contact with the metal separation plate. As such, heat generated by the heat source zone can be subjected to heat exchange with the metal separation plate through a radiating way in order to lower the temperature of the heat source zone. The refrigeration device functions to remove the heat absorbed by the metal separation plate.

### BACKGROUND OF THE INVENTION

### (a) Technical Field of the Invention

The present invention relates to a cooling and temperature-lowering system, and more particularly to an energy-radiating cooling and temperature-lowering system that effectively enhance the heat dissipation efficiency without involving liquid cooling.

### (b) Description of the Prior Art

“Heat dissipation” is a topic that is often mentioned in the recent era of Industry 4.0 and information technology, because any equipment or device that needs to work will generate heat. If the heat cannot be effectively removed in time, it will affect the operating efficiency at the least, and even cause work to stop.

A heat dissipation module is a technology or structure designed to effectively dissipate or reduce the heat generated in a device or system. These modules typically include a variety of heat dissipation components to help control the temperature of the device so as to ensure it functions properly. The heat dissipation module can adopt a variety of different heat dissipation technologies to improve the efficiency and reliability of operation, and the most common ones are: air cooling, water cooling, and immersion cooling.

Servers often need to run for long periods of time, processing large amounts of data and applications, and this will generate a lot of heat. If such heat is not handled effectively, server performance may degrade or even cause hardware damage. Conventional server cooling methods and techniques are described as follows:
Fan cooling system: servers are usually equipped with fan cooling systems to draw air from the server chassis to cool the internal components; however, with the increasing popularity of high-speed computing servers, traditional fan cooling methods can no longer meet the needs.
Heat sinks and radiators: heat sinks and radiators are devices used to increase surface area to improve heat dissipation. They are usually used to connect to the CPU and other high-temperature components to transfer heat to a large-area aluminum or copper radiator to improve heat dissipation efficiency. This way of heat dissipation also cannot meet the needs of high-speed computing servers.
Liquid cooling system: some high-performance servers use a liquid cooling system, in which liquid flows through pipes and radiators to carry away heat. These systems are generally more efficient than air cooling and are particularly well suited for server applications where efficient heat dissipation is required. However, if the components used to convey the liquid, such as pipes and joints, are damaged or cracked, the leaking liquid may cause short circuiting or even damage the electronic components.

### SUMMARY OF THE INVENTION

An objective of the present invention is to solve the problem that the traditional fan cooling and heat sink-and-radiator cooling cannot meet the needs of high-speed computing servers that generate a large amount of heat, while the liquid cooling system has problems when the components that convey liquid, such as pipes and joints, are damaged or cracked, the leaking liquid may cause shorting of circuits or even damage electronic components.

The present invention provides an energy-radiating cooling and temperature-lowering system, which comprises: a refrigeration zone, in which a refrigeration device is arranged; a heat source zone, which is adjacent to the refrigeration zone, a humidity controller being arranged in the heat source zone; and a metal separation plate, which is arranged between the refrigeration zone and the heat source zone to serve as a heat exchange element between the refrigeration zone and the heat source zone, wherein the refrigeration device comprises a coolant pipe, and the coolant pipe is in contact engagement with the metal separation plate. As such, heat generated by the heat source zone can be exchanged with the cold metal separation plate by radiation in a high efficiency manner to lower the temperature of the heat source zone. The refrigeration device functions to remove the heat absorbed by the metal separation plate, without any concern that liquid causes shorting of circuits and damages to electronic components.

In an embodiment of the present invention, the coolant pipe is arranged in contact engagement with a surface of a first side of the metal separation plate. As such, the coolant pipe may bring away the heat absorbed by the metal separation plate.

In another embodiment of the present invention, the first side of the metal separation plate is formed with a recessed groove, and the coolant pipe is arranged in the recessed groove and in contact engagement with the metal separation plate. As such, an increased surface contact area is provided between the coolant pipe and the metal separation plate to thereby allow the coolant pipe to more efficiently bring away the heat absorbed by the metal separation plate.

Preferably, a second side of the separation plate of the present invention may be formed with a plurality of fins, and the fins are extended into the heat source zone. As such, the plurality of fins may expand the contact surface area between the metal separation plate and the heat source zone to more efficiently absorb heat.

In an embodiment of the present invention, the heat source zone is a server cabinet, and the refrigeration zone is a space in an interior of the server cabinet separated by the metal separation plate.

Preferably, the present invention provides a fan arranged on a wall of the server cabinet. As such, assistance of removing heat from the heat source zone may be achieved to further improve the efficiency of heat dissipation and cooling.

In an embodiment of the present invention, the refrigeration device comprises a refrigerator, and the refrigerator is arranged at an outside of the server cabinet and connected to two ends of the coolant pipe by an inlet pipe and an outlet pipe.

### BRIEF DESCRIPTION OF THE DRAWINGS

FIG. 1 is a perspective view showing a cooling and temperature-lowering system according to the present invention used in a server cabinet;

FIG. 2 is a front view showing the cooling and temperature-lowering system according to the present invention used in a server cabinet;

FIG. 3 is a lateral side cross-sectional view of FIG. 2;

FIG. 4 is a schematic plan view showing arrangement of a coolant pipe on a first side surface of a metal separation plate according to another embodiment of the present invention; and

FIG. 5 is a cross-sectional view taken along line V-V of FIG. 4.

### DETAILED DESCRIPTION OF THE PREFERRED EMBODIMENTS

A more detailed description of the implementation of the present invention is provided below with reference to the drawings and component signs, so that those skilled in the art can implement the invention after reading the disclosure.

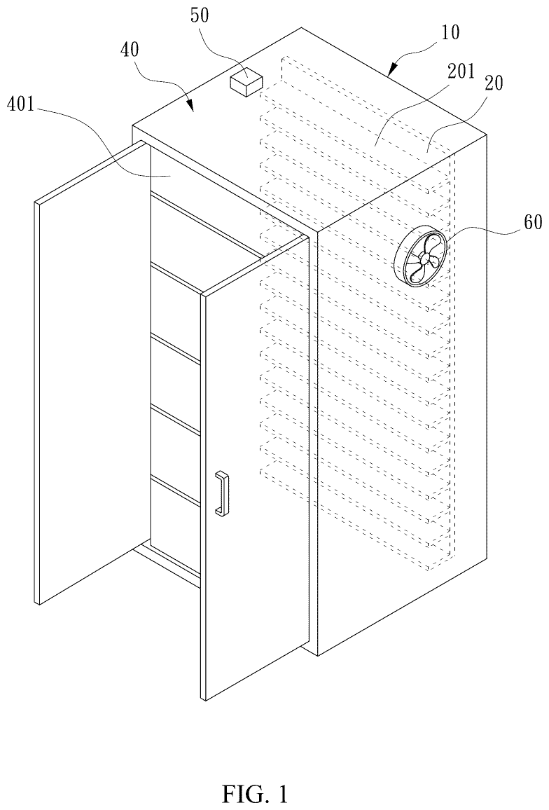

FIGS. 1-3 show an embodiment of an energy-radiating cooling and temperature-lowering system according to the present invention used in a server cabinet, wherein an interior of the cabinet is divided by a metal separation plate 20 having excellent heat conductivity into a refrigeration zone 10 and a heat source zone 40, meaning the refrigeration zone 10 and the heat source zone 40 are arranged adjacent to each other. Speaking in a more specific way, the heat source zone 40 is located at a front part of the cabinet, and after a door is opened, the server 401 can be placed therein or removed therefrom. The refrigeration zone 10 is located at a rear part of the cabinet, and through the metal separation plate 20 absorbing heat generated by the server 401, the heat can be removed by a refrigeration device 30 arranged in the refrigeration zone 10. Preferably, the metal separation plate 20 has a first side (which is a side facing the rear of the cabinet) in contact engagement with and connected to the refrigeration device 30, and the metal separation plate 20 has a second side (which is a side facing the front of the cabinet) that is provided with a plurality of fins 201, where the fins 201 are extended into the heat source zone 40 to expand an area of the metal separation plate 20 for contacting heat, thereby serving as a heat exchange element between the refrigeration zone and the heat source zone.

The refrigeration device 30 comprises a refrigerator 301 and a coolant pipe 302. The refrigerator 301 is arranged at an outside of the server cabinet. The coolant pipe 301 is arranged in contact engagement with the first side of the metal separation plate 20. The coolant pipe 301 has two ends at which a first end opening 3021 and a second end opening 3022 are respectively arranged to respectively connect to an outlet pipe 304 and an inlet pipe 303. The outlet pipe 304 and the inlet pipe 303 are respectively connected to an egress opening and an ingress opening of the refrigerator 301. The refrigerator 301 comprises refrigeration cycle components that are made up of a compressor and a driving motor, a condenser, an expansion valve, and a coolant pipe 301 (which is an evaporator). During a process performed through the refrigeration cycle, the compressor receives a coolant gas after evaporation by the evaporator and compresses the coolant gas to become high-pressure gaseous coolant. The gaseous coolant flows into the condenser, and is subjected to cooling and heat dissipating by surrounding air or water so that the gaseous coolant gets condensed into high-pressure normal-temperature liquid coolant. The high-pressure liquid coolant flowing out of the condenser is subjected to pressure drop through the expansion valve so that the coolant flowing therethrough becomes low-pressure liquid coolant. The low-pressure liquid coolant is conveyed to the coolant pipe 301 to absorb heat conducted from the heat source zone 40 by the metal separation plate 20 to thereby become gaseous coolant, which flows back the compressor to repeat another round of the refrigeration cycle.

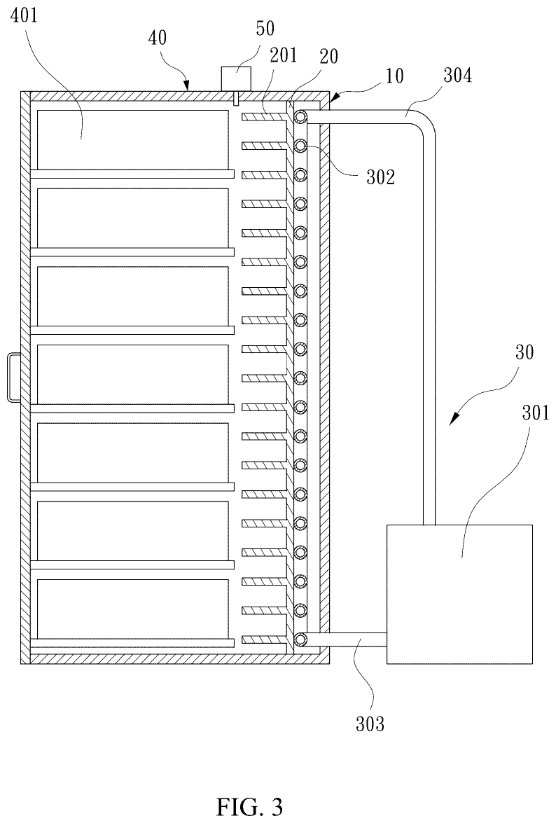

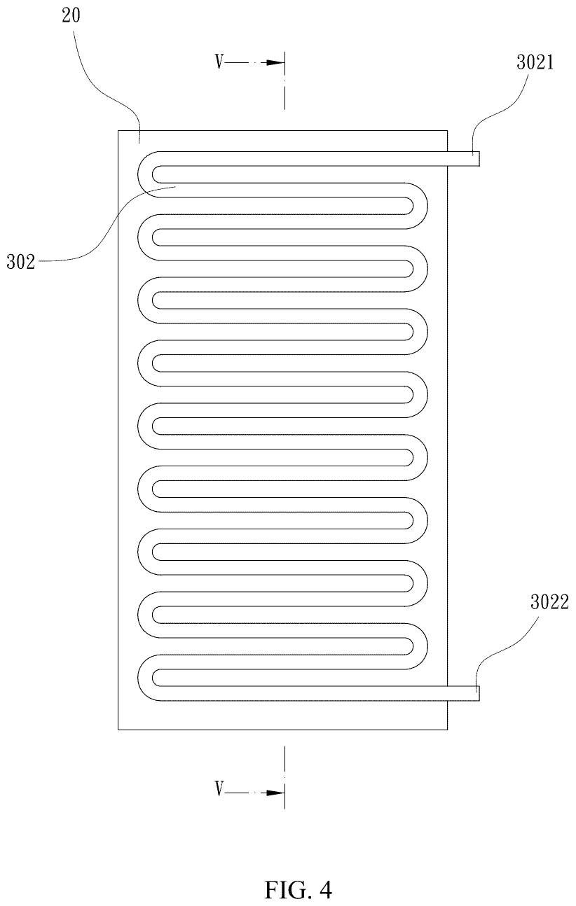

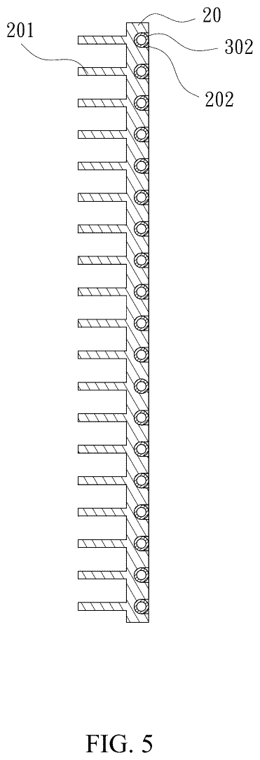

In an embodiment of the present invention, the coolant pipe 301 is placed in contact engagement with a surface of the first side of the metal separation plate 20 (see FIG. 3). Or alternatively, in another embodiment of the present invention, the first side of the metal separation plate 20 is structured to form a circuitous recessed groove 202 corresponding to the coolant pipe 301 (see FIGS. 4 and 5), so as to expand a contact area with the metal separation plate 20 with the coolant pipe 301 disposed and set in the recessed groove 202, to thereby allow the coolant pipe 301 to bring away the heat absorbed by the metal plate 20 in a higher efficiency.

With the above-described cooling and temperature-lowering system according to the present invention, heat generated by the operation of the server 401 located in the heat source zone 40 can be absorbed, in a radiating form, by the metal separation plate 20 and the fins 201, and is then subjected to high-efficiency heat exchange through the cold coolant pipe 301 so as to lower the temperature of the heat source zone 40 in a high-efficiency manner. Further, as the heat is removed by the refrigeration device 30, through the entire cooling and temperature lowering process, the server is completely prevented from contacting liquid, so that there is no concern that liquid causes shorting of a circuit and damages electronic components.

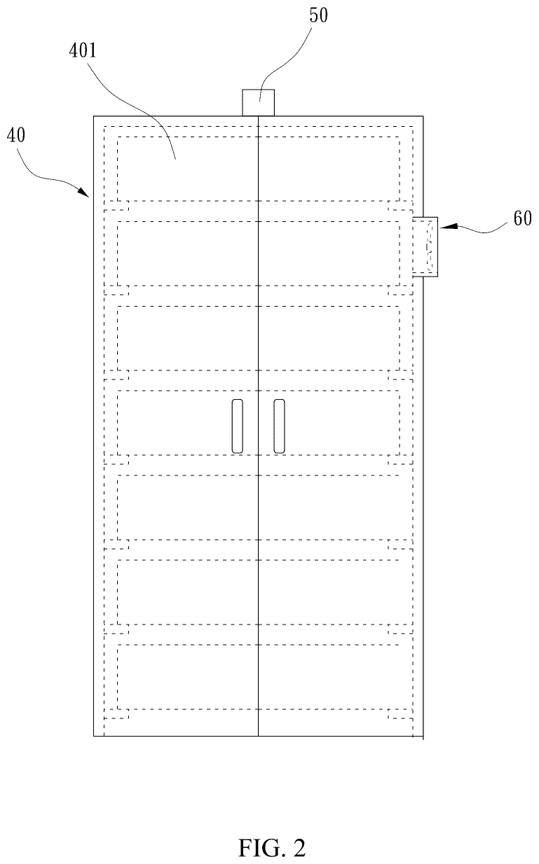

Further, the present invention may further provide a fan 60 and a humidity controller 50 arranged on a wall of the server cabinet (see FIGS. 1 and 2). The fan 60 helps remove heat from the interior of the heat source zone 40 to further enhance the efficiency of cooling. The humidity controller 50 monitors humidity in the heat source zone 40 to avoid negative influence on the sever caused by high humidity.

I claim:

1. An energy-radiating cooling and temperature-lowering system, comprising:
a refrigeration zone, in which a refrigeration device is arranged;
a heat source zone, which is adjacent to the refrigeration zone, a humidity controller being arranged in the heat source zone; and
a metal separation plate, which is arranged between the refrigeration zone and the heat source zone to serve as a heat exchange element between the refrigeration zone and the heat source zone,
wherein the refrigeration device comprises a coolant pipe, and the coolant pipe is in contact engagement with the metal separation plate.

2. The energy-radiating cooling and temperature-lowering system according to claim 1, wherein the coolant pipe is in contact engagement with a surface of a first side of the metal separation plate.

3. The energy-radiating cooling and temperature-lowering system according to claim 1, wherein the metal separation plate has a first side that is formed with a recessed groove, and the coolant pipe is arranged in the recessed groove and in contact engagement with the metal separation plate.

4. The energy-radiating cooling and temperature-lowering system according to claim 1, wherein the metal separation plate has a second side on which a plurality of fins are formed, the fins being extended into the heat source zone.

5. The energy-radiating cooling and temperature-lowering system according to claim 1, wherein the heat source zone is a server cabinet, and the refrigeration zone is a space in an interior of the server cabinet separated by the metal separation plate.

6. The energy-radiating cooling and temperature-lowering system according to claim 5, wherein a fan is arranged on a wall of the server cabinet.

7. The energy-radiating cooling and temperature-lowering system according to claim 5, wherein the refrigeration device comprises a refrigerator, the refrigerator being arranged at an outside of the server cabinet and being connected to two ends of the coolant pipe by an inlet pipe and an outlet pipe.
